(19) United States
(12) Patent Application Publication
(10) Pub. No.: US 2025/0354946 A1
(43) Pub. Date: Nov. 20, 2025

(54) Particle Analysis Apparatus and Method

(71) Applicant: JEOL Ltd., Tokyo (JP)

(72) Inventors: Kei Nagatomo, Tokyo (JP); Takeshi Otsuka, Tokyo (JP)

(21) Appl. No.: 19/210,111

(22) Filed: May 16, 2025

(30) Foreign Application Priority Data
May 20, 2024 (JP) 2024-081638

(51) Int. Cl. G01N 23/2251; G06T 5/40; H01J 37/22; H01J 37/28

(52) U.S. Cl. CPC G01N 23/2251; G06T 5/40; H01J 37/222; H01J 37/28; G01N 2223/418; H01J 2237/24475

(57) ABSTRACT

An angle calculator calculates, for each coordinate in a beam scanning range, an angle representing an orientation of a plane based on an intensity distribution. A normalizer multiplies an angle array produced by the angle calculator by a numerical value corresponding to a shape of interest (for example, a needle shape or a string shape). A particle-of-interest analyzer analyzes whether a candidate particle is a particle of interest, based on a group of normalized angles corresponding to the candidate particle.

### CROSS REFERENCE TO RELATED APPLICATION

This application claims priority to Japanese Patent Application No. 2024-081638 filed May 20, 2024, the disclosure of which is hereby incorporated by reference in its entirety.

### BACKGROUND OF THE DISCLOSURE

### Field of the Disclosure

The present disclosure relates to a particle analysis apparatus and a particle analysis method, and in particular to a technique for identifying a particle having a particular shape.

### Description of Related Art

Known particle measurement systems include an electron microscope system, a laser microscope system, an optical microscope system, and the like. For example, the electron microscope system which measures particles is formed from a scanning electron microscope having a backscattered electron detector, and an information processing apparatus equipped with particle analysis software. The latter device, the information processing apparatus, may also be called a particle analysis apparatus.

For example, when an asbestos particle (a fiber element forming asbestos) in a powder dust sample is to be measured and analyzed, an aspect ratio for each candidate particle is calculated by the particle analysis software, and whether or not the candidate particle is the asbestos particle is identified based on the aspect ratio. Because the asbestos particle has a very narrow shape (a needle shape or a string shape), it is not easy to distinguish the asbestos particle from other elongated particles, elongated scars, or the like. When a plurality of asbestos particles mutually overlap and intersect, it is difficult to accurately calculate the aspect ratio.

When counting of the asbestos particles or the like is to be performed while identifying, with human eyes, each asbestos particle included in an image produced by the scanning electron microscope, a significant burden is caused for an inspector, and a variation tends to be caused in the analysis result depending on the inspector. In a particle analysis apparatus, particles other than the asbestos particle may be analyzed.

Document 1 (JP 2007-155515 A) and Document 2 (JP 2021-165657 A) disclose a particle measurement system. Document 3 (JP 2022-185757 A) discloses a system which analyzes a shape of a sample surface. Document 4 (JP 2019-121588A) discloses a system which measures a diffraction pattern. Documents 1 to 4 do not disclose a technique for identifying a particle of interest having a particular shape. In particular, Documents 1 to 4 do not disclose a technique for identifying a particle of interest having a particular shape utilizing rotational symmetry.

### SUMMARY OF THE DISCLOSURE

An advantage of the present disclosure lies in precise identification of a particle of interest. Alternatively, an advantage of the present disclosure lies in precise identification of a particle of interest having a needle shape or a string shape. Further alternatively, an advantage of the present disclosure lies in identification of each individual particle of interest when a plurality of particles of interest overlap each other.

According to one aspect of the present disclosure, there is provided a particle analysis apparatus comprising: a calculator that calculates, for each coordinate in a beam scanning range on a sample, an angle representing an orientation of a plane at the coordinate, based on an intensity distribution acquired by detecting a signal emitted from the coordinate with a detection region array; a normalizer that applies normalization corresponding to a shape of interest with respect to a plurality of angles corresponding to a plurality of coordinates in the beam scanning range, to thereby calculate a plurality of normalized angles; and an analyzer that analyzes, for each candidate particle in the beam scanning range, whether or not the candidate particle is a particle of interest, based on a group of normalized angles corresponding to the candidate particle.

According to another aspect of the present disclosure, there is provided a method of analyzing a particle, the method comprising: a step of calculating, for each coordinate in a beam scanning range on a sample, an angle representing an orientation of a plane at the coordinate based on an intensity distribution acquired by detecting a signal emitted from the coordinate with a detection region array; a step of applying normalization corresponding to a shape of interest with respect to a plurality of angles corresponding to a plurality of coordinates in the beam scanning range, to thereby calculate a plurality of normalized angles; and a step of analyzing, for each candidate particle in the beam scanning range, whether or not the candidate particle is a particle of interest, based on a group of normalized angles corresponding to the candidate particle.

### BRIEF DESCRIPTION OF THE DRAWINGS

Embodiment(s) of the present disclosure will be described based on the following figures, wherein:

FIG. 1 is a block diagram showing a particle measurement system according to an embodiment of the present disclosure;

FIG. 2 is a flowchart showing a method of analyzing a particle according to an embodiment of the present disclosure;

FIG. 3 is a diagram showing a backscattered electron detector;

FIG. 4 is a diagram showing an example of an intensity distribution;

FIG. 5 is a diagram showing another example of the intensity distribution;

FIG. 6 is a diagram showing a detection coordinate system;

FIG. 7 is a diagram showing a vector calculated from the intensity distribution;

FIG. 8 is a diagram showing a color space;

FIG. 9 is a diagram showing a convex region and a concave region;

FIG. 10 is a diagram showing two vectors acquired from two inclined surfaces in a first shape;

FIG. 11 is a diagram showing three vectors acquired from three inclined surfaces in a second shape;

FIG. 12 is a diagram showing four vectors acquired from four inclined surfaces in a third shape;

FIG. 13 is a diagram showing an asbestos particle;

FIG. 14 is a diagram showing a composite vector;

FIG. 15 is a diagram showing extraction of a convex region;

FIG. 16 is a diagram showing shape analysis based on dispersion information;

FIG. 17 is a diagram showing a histogram;

FIG. 18 is a diagram showing shape analysis based on the histogram;

FIG. 19 is a diagram showing division of a candidate particle;

FIG. 20 is a diagram showing a backscattered electron image and a particle-of-interest image; and

FIG. 21 is a diagram showing an example of image analysis.

### DESCRIPTION OF NON-LIMITING EMBODIMENTS

An embodiment of the present disclosure will now be described with reference to the drawings.

### (1) Overview of Embodiment

A particle analysis apparatus according to an embodiment of the present disclosure comprises a calculator, a normalizer, and an analyzer. The calculator calculates, for each coordinate in a beam scanning range (a beam scanning region) on a sample, an angle representing an orientation of a plane at the coordinate, based on an intensity distribution acquired by detecting a signal emitted from the coordinate with a detection region array. The normalizer applies normalization corresponding to a shape of interest with respect to a plurality of angles corresponding to a plurality of coordinates in the beam scanning range, to thereby calculate a plurality of normalized angles. The analyzer analyzes, for each candidate particle in the beam scanning range, whether or not the candidate particle is a particle of interest, based on a group of normalized angles corresponding to the candidate particle. A processor to be described below functions as the calculator, the normalizer, and the analyzer.

The normalization described above is a mathematical operation to cause uniformity in a group of angles acquired from a shape of interest, and at the same time to cause diversity in a group of angles acquired from a shape other than the shape of interest. With such a pre-process as a presumption, a group of normalized angles corresponding to the candidate particle is evaluated, to determine whether or not the candidate particle is a particle of interest. The particle of interest is an analysis target particle having the shape of interest.

For example, whether or not the candidate particle is the particle of interest may be identified based on information indicating a degree of variation of the group of normalized angles corresponding to the candidate particle. As the information indicating the degree of variation, there may be exemplified dispersion information, a histogram, and the like. Alternatively, the candidate particle may be analyzed based on other evaluation values.

In an embodiment, the normalizer calculates the plurality of normalized angles by multiplying each of the plurality of angles by a coefficient corresponding to the shape of interest. This structure selectively normalizes the plurality of angles acquired from the shape of interest utilizing the rotational symmetry of the shape of interest. More specifically, with the normalization, the plurality of angles acquired from the candidate particle are made uniform into a particular angle or within a particular angle range. In an embodiment, the shape of interest is a needle shape or a string shape. In this case, the above-described coefficient is 2. Alternatively, as the method of normalization, a method other than the coefficient multiplication may be employed.

A particle analysis apparatus according to an embodiment of the present disclosure comprises a determiner that determines a convex region in the beam scanning range as the candidate particle (candidate particle region) based on the plurality of angles corresponding to the plurality of coordinates. According to this structure, it is possible to exclude a concave region (for example, scars and recesses) from the analysis target. The processor to be described below functions as the determiner.

In an embodiment of the present disclosure, the determiner extracts the convex region by applying calculation for determining divergences with respect to the plurality of angles corresponding to the plurality of coordinates. This structure applies a vector calculation on an angle array, assuming that the angle array is a vector field. A group of positive divergences corresponds to the convex region.

In an embodiment of the present disclosure, the analyzer calculates dispersion information based on the group of normalized angles corresponding to the candidate particle. The analyzer analyzes whether or not the candidate particle is the particle of interest based on the dispersion information. The dispersion information indicates a degree of uniformity of the group of normalized angles.

In an embodiment of the present disclosure, the analyzer creates a histogram based on the group of normalized angles corresponding to the candidate particle. The analyzer analyzes whether or not the candidate particle is the particle of interest, based on the histogram. The histogram has an angle axis and a frequency axis. Through analysis of the histogram, the group of normalized angles can be evaluated in detail.

In an embodiment of the present disclosure, the analyzer determines that a shape of the candidate particle is a combination of a plurality of shapes of interest based on the histogram. The analyzer separates the candidate particle into a plurality of particles of interest when the shape of the candidate particle is a combination of the plurality of shapes of interest. According to this structure, when a plurality of particles of interest mutually overlap, each individual particle of interest can be separated and identified.

A method of analyzing a particle according to an embodiment of the present disclosure comprises a first step, a second step, and a third step. In the first step, for each coordinate in a beam scanning range on a sample, an angle representing an orientation of a plane at the coordinate is calculated based on an intensity distribution acquired by detecting a signal emitted from the coordinate with a detection region array. In the second step, normalization corresponding to a shape of interest is applied with respect to a plurality of angles corresponding to a plurality of coordinates in the beam scanning range, to thereby calculate a plurality of normalized angles. In the third step, for each candidate particle in the beam scanning range, it is analyzed whether or not the candidate particle is a particle of interest based on a group of normalized angles corresponding to the candidate particle.

The particle analysis method described above may be realized, for example, by software. A program for executing the particle analysis method is installed in an information processing apparatus via a network or a transportable recording medium. The information processing apparatus has a non-transitory recording medium which stores a program.

### (2) Details of Embodiment

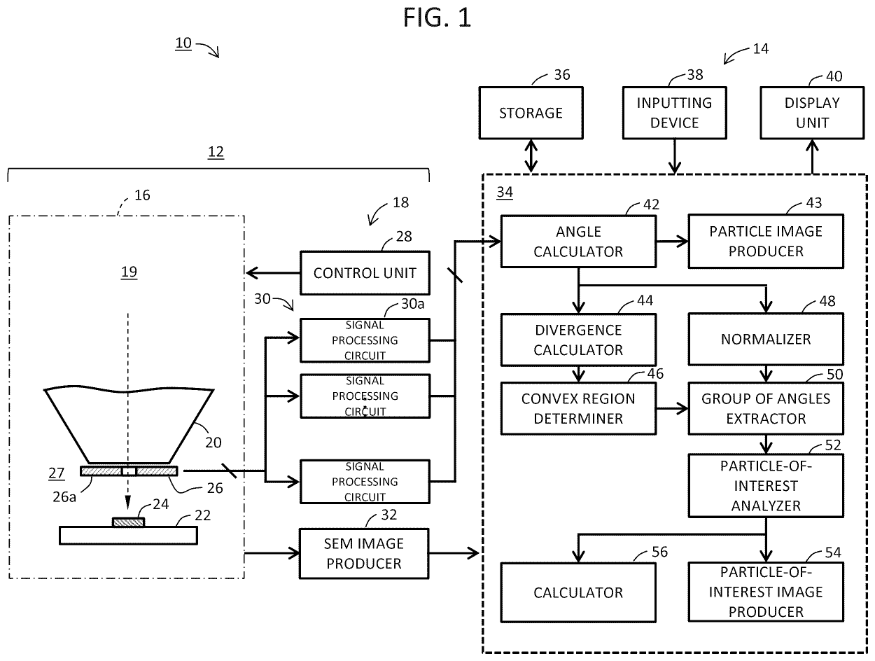

FIG. 1 shows a particle measurement system 10 according to an embodiment of the present disclosure. The particle measurement system 10 measures one or a plurality of asbestos particles contained in a sample 24. The asbestos particle is a very small, needle-shaped or string-shaped particle. Alternatively, other particles may be measured with the particle measurement system 10.

The particle measurement system 10 includes a scanning electron microscope 12 and an information processing apparatus 14. The scanning electron microscope 12 includes a measurement unit 16 and a calculation control unit 18. The measurement unit 16 has an optical column. The optical column includes an electron gun 19, an objective lens 20, a backscattered electron detector 26, a sample chamber 27, and the like. A movable stage 22 is provided in the sample chamber 27. The sample 24 is held by the movable stage 22. The sample 24 is, for example, a powder dust including asbestos. In FIG. 1, the sample 24 is represented in an emphasized manner.

Over a two-dimensional beam scanning range which is set with respect to the sample 24, an electron beam is two-dimensionally scanned. Specifically, the beam scanning range is formed from a plurality of coordinates (a plurality of measurement points), and an electron beam is sequentially illuminated onto the plurality of coordinates. Backscattered electrons emitted from each coordinate are detected by the backscattered electron detector 26.

The backscattered electron detector 26 is provided between the objective lens 20 and the sample 24. Specifically, the backscattered electron detector 26 is placed near a lower end surface of the objective lens 20. The backscattered electron detector 26 is formed from a plurality of detection regions 26a arranged in an annular shape. The plurality of detection regions 26a may be called a detection region set. At a center part of the backscattered electron detector 26, an opening for letting the electron beam to pass through is formed. A plurality of detection signals are output from the plurality of detection regions 26a in parallel with each other. The plurality of detection signals may be called a detection signal set. Alternatively, the plurality of detection signals may be output from the backscattered electron detector 26 in a time divisional manner. The number of the detection regions 26a forming the backscattered electron detector 26 is, for example, 4, 6, 8, 12, or 16. It should be noted that the numerical values described herein are merely exemplary.

In the optical column, a secondary electron detector (not shown) is also placed. As the secondary electron detector, a secondary electron detector having a plurality of detection regions may be placed.

The calculation control unit 18 includes a control unit 28, a signal processor 30, an SEM (Scanning Electron Microscopy) image producer 32, and the like. The control unit 28 controls operations of the measurement unit 16. The SEM image producer 32 forms an SEM image based on the detection signal which is output from the secondary electron detector or the detection signal set which is output from the backscattered electron detector. The formed SEM image is sent to the information processing apparatus 14 as necessary.

The signal processor 30 is formed from a plurality of signal processing circuits 30a which process a plurality of detection signals respectively output from the plurality of detection regions 26a of the backscattered electron detector 26. Each signal processing circuit 30a includes, for example, a current-to-voltage converter, an amplifier, an A/D converter, and the like. A plurality of detection data which are output from the signal processor 30 are sent to the information processing apparatus 14. The plurality of detection data may be called a detection data set. The detection data set acquired from each coordinate represents an intensity distribution on a detection surface of the backscattered electron detector 26. In other words, the detection data set is data representing the intensity distribution.

The intensity distribution reflects a shape of the measurement point from which the backscattered electrons are emitted. That is, the intensity distribution varies depending on an orientation of a minute plane (sample plane, particle plane) at the measurement point. More specifically, an angle of a primary axis (normally, a center axis) of the intensity distribution varies depending on a direction of inclination of the minute plane. Therefore, the orientation of the plane at the measurement point can be estimated based on the angle of the primary axis of the intensity distribution.

The information processing apparatus 14 is a particle analysis apparatus. The information processing apparatus 14 is formed from a computer having particle analysis software. More specifically, the information processing apparatus 14 has a processor 34, a storage 36, an inputting device 38, and a display unit 40. FIG. 1 shows a plurality of functions realized by the processor 34 as a plurality of blocks. The processor 34 includes, for example, a CPU or a GPU. Alternatively, the processor 34 may be formed from a plurality of information processing devices.

An angle calculator 42 calculates an angle of the primary axis of the intensity distribution based on the detection data set acquired from each coordinate in the sample; that is, the intensity distribution. Alternatively, the angle calculator 42 may calculate intensity together with the angle. In this case, the angle calculator 42 may be viewed as a vector calculator. With the angle calculator 42, a plurality of angles corresponding to the plurality of coordinates in the beam scanning range; that is, an angle array, is calculated.

A particle image producer 43 produces a particle image based on the angle array. In this process, the angle may be converted into hue or a combination of the angle, and the intensity may be converted into a combination of the hue and brightness.

A divergence calculator 44 applies a vector calculation on the angle array, presuming that the angle array is assumed to be a vector field. More specifically, the divergence calculator 44 applies a calculation for determining the divergences on the angle array. With this process, a plurality of divergences (divergence array) corresponding to the plurality of coordinates are determined. A group of positive divergences corresponds to a convex region, and a group of negative divergences corresponds to a concave region.

A convex region determiner 46 determines one or a plurality of convex regions in the beam scanning range based on the divergence array. In other words, the convex region determiner 46 excludes concave portions such as scars and recesses from the analysis target. Each convex region is handled as a candidate region.

A normalizer 48 applies a mathematical operation which selectively acts on the shape of interest (mathematical operation utilizing rotational symmetry) with respect to the angle array. More specifically, the normalizer 48 multiplies the angle array by a coefficient corresponding to the shape of interest, to thereby produce a normalized angle array. In the embodiment of the present disclosure, as described above, the particle of interest is the asbestos particle. The shape of interest is an elongated shape (needle shape, string shape). In this case, the coefficient for normalization is 2.

A group-of-angles extractor 50 extracts, for each candidate particle (candidate particle region) which is the convex region, a group of normalized angles corresponding to the candidate particle from among the angle array. That is, the group-of-angles extractor 50 extracts a group of normalized angles belonging to the candidate particle or acquired from the candidate particle.

When the candidate particle has the shape of interest, the group of normalized angles corresponding to the candidate particle exhibit uniformity. When the candidate particle has a shape other than the shape of interest, the group of normalized angles acquired from the candidate particle exhibit diversity.

A particle-of-interest analyzer 52 evaluates, for each candidate particle, the group of normalized angles corresponding to the candidate particle, to thereby analyze whether or not the candidate particle is the particle of interest. As an analysis method, a first analysis method and a second analysis method may be employed. In the first analysis method, dispersion information is calculated based on the group of normalized angles, and the shape of the candidate particle is evaluated based on the dispersion information. In the second analysis method, a histogram (angle histogram) is created based on the group of normalized angles, and the candidate particle is evaluated based on the histogram.

A particle-of-interest image producer 54 forms an image of one or a plurality of particles of interest. The produced particle-of-interest image is displayed on the display unit 40. The particle of interest corresponds to a convex region having a form of a needle shape or a string shape.

A calculator 56 executes counting of the particles of interest, calculation of an aspect ratio of each particle of interest, or the like in the beam scanning range. A result of analysis of the particle of interest is displayed on the display unit 40. The display unit 40 is formed from, for example, an LCD.

The inputting device 38 is formed from a keyboard, a pointing device, or the like. The user designates particle analysis condition or the like using the inputting device 38. The storage 36 stores parameters or the like which are referred to in the particle analysis. In addition, the storage 36 also stores the particle analysis software. Alternatively, the particle-of-interest image and the SEM image may be displayed in parallel with each other or in an overlapping manner.

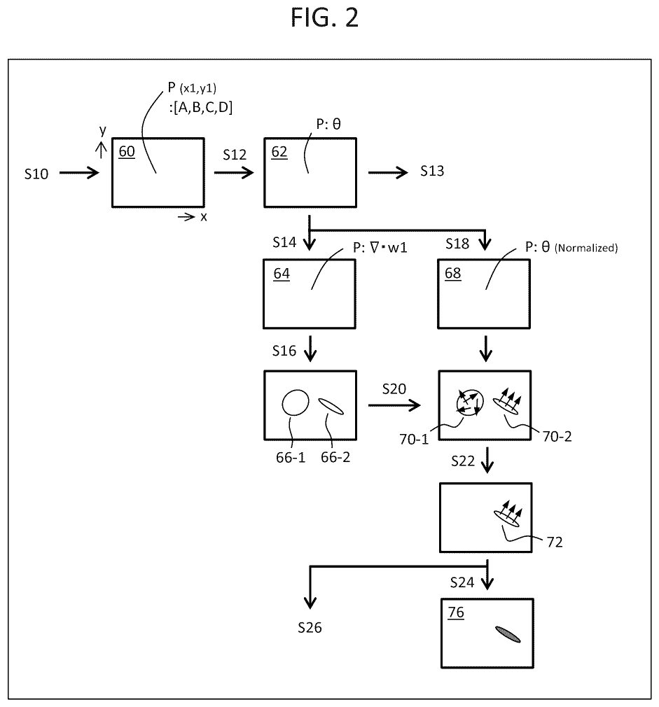

FIG. 2 shows a particle analysis method according to the embodiment of the present disclosure as a flowchart. In S10, the sample is measured using the scanning electron microscope. With this process, an intensity distribution array 60 is produced. The intensity distribution array 60 is formed from a plurality of intensity distributions corresponding to a plurality of coordinates in the two-dimensional beam scanning range. The beam scanning range has an x axis and a y axis. FIG. 2 shows signal intensities A, B, C, and D which form an intensity distribution acquired from a coordinate P (x1, y1).

In S12, an angle calculation is applied with respect to the intensity distribution array formed from the plurality of intensity distributions corresponding to the plurality of coordinates. With this process, an angle array 62 is produced. FIG. 2 shows an angle θ corresponding to the coordinate P. In S13, a color particle image is produced based on the angle array 62 as necessary.

In S14, a calculation for determining divergences is applied with respect to the angle array 62. With this process, a divergence array 64 is produced. FIG. 2 shows a divergence (∇·w1) corresponding to the coordinate P. The divergence (∇·w1) will be described later in detail. In S16, one or a plurality of convex regions are identified based on the divergence array. In this process, processes such as binarization, labeling, and the like are sequentially applied with respect to the divergence array. FIG. 2 shows two convex regions 66-1 and 66-2 that are extracted. Each of the convex regions 66-1 and 66-2 is handled as a candidate particle.

In S18, normalization is applied with respect to the angle array 62. More specifically, each angle of the angle array 62 is multiplied by 2 serving as a coefficient. FIG. 2 shows a normalized angle θ correlated to the coordinate P.

In S20, for each candidate particle, a group of normalized angles corresponding to the candidate particle are extracted from the normalized angle array. FIG. 2 shows two groups of normalized angles 70-1 and 70-2 corresponding to the two convex regions 66-1 and 66-2.

In S22, each of the groups of normalized angles 70-1 and 70-2 is evaluated. Specifically, based on each of the groups of normalized angles 70-1 and 70-2, the shape of each of the candidate particles is evaluated. With this process, a particle of interest (particle-of-interest region) 72 having a form of a needle shape or a string shape is selected. In S24, a particle-of-interest image 76 is produced by forming an image of the particle of interest 72. In S26, measurement is performed with respect to the particle of interest 72.

As described, according the embodiment of the present disclosure, with acquisition of the intensity distribution array as a presumption, the particle of interest can be precisely extracted using both the convex region determination and the normalization. Alternatively, in place of a segmented backscattered electron detector, a segmented secondary electron detector may be employed.

A method of analyzing a particle according to the embodiment of the present disclosure will now be described in detail.

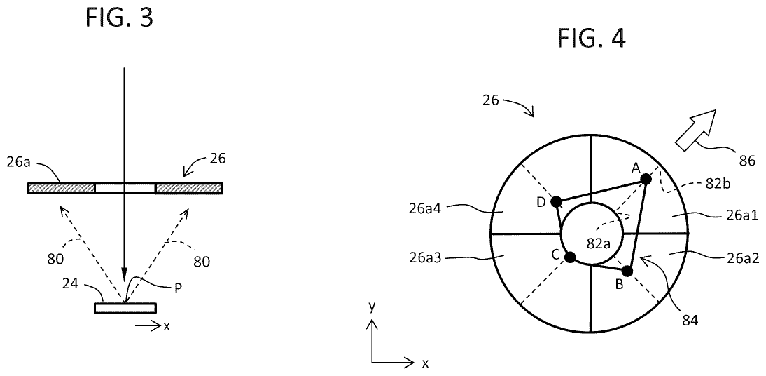

FIG. 3 shows the backscattered electron detector 26. The backscattered electron detector 26 is formed from a plurality of detection regions 26a arranged in a manner to surround an optical axis. A signal emitted from the coordinate P on the sample 24; that is, a backscattered electron 80, is detected by each detection region 26a. The signal intensity observed in each of the detection regions 26a depends on a concave-convex shape of the sample, more specifically, an orientation of a minute plane at the coordinate P.

FIG. 4 shows an example of the intensity distribution. In the illustrated example, the backscattered electron detector 26 is formed from four detection regions 26al to 26a4 placed on an xy plane. Each of the detection regions 26al to 26a4 has a shape of a fan. In FIG. 4, a center axis of each of the detection regions 26al to 26a4 is shown with a dotted line. In FIG. 4, signal intensities A to D observed in the four detection regions 26al to 26a4 are plotted on the four center axes. With the signal intensities A to D, an intensity distribution 84 similar to a radar chart is formed. An orientation of the intensity distribution (an orientation of the primary axis of the intensity distribution 84 or an extension orientation of the intensity distribution 84) is shown by reference numeral 86. At each center axis, an inner end 82a corresponds to the smallest intensity, and an outer end 82b corresponds to the greatest intensity.

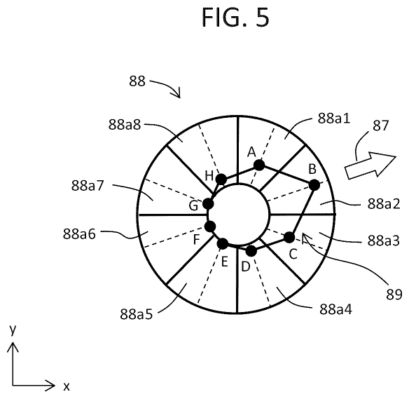

FIG. 5 shows another example of the intensity distribution. A backscattered electron detector 88 is formed from 8 detection regions 88al to 88a8 arranged in an annular shape. An intensity distribution 89 is formed by 8 signal intensities A to H observed at the 8 detection regions 88a1 to 88a8. An orientation (angle) of the intensity distribution 89 is shown by reference numeral 87.

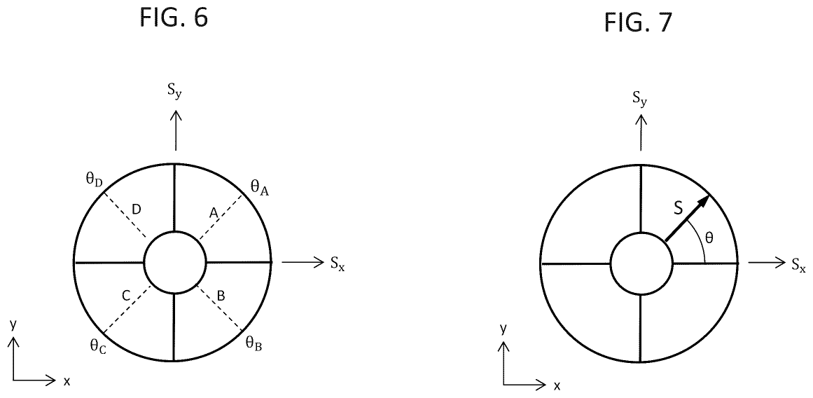

FIG. 6 shows a detection coordinate system. The intensity distribution may be converted into a vector as described below. As the conversion method, a first conversion method and a second conversion method may be employed. The first conversion method will be described first.

In FIG. 6, the backscattered electron detector is formed from four detection regions, and four signal intensities observed in the four detection regions are signal intensities A to D. The center axes of the four detection regions may be defined by angles θ_{A} to θ_{D}.

When synthesis of the four signal intensities A to D is considered, an x component (Sx) and a y component (Sy) after the synthesis are represented by following Equations (1) and (2).

$${S}_{x} = \frac{A cos {θ}_{A} + B cos {θ}_{B} + C cos {θ}_{C} + D cos {θ}_{D}}{A + B + C + D} \qquad ( 1 )$$

$${S}_{y} = \frac{A sin {θ}_{A} + B sin {θ}_{B} + C sin {θ}_{C} + D sin {θ}_{D}}{A + B + C + D} \qquad ( 2 )$$

When the intensity distribution is represented by a vector (refer to FIG. 7), a size S and an angle θ of the vector are represented by the following Equations (3) and (4).

$$S = \sqrt{{S}_{x}^{2} + {S}_{y}^{2}} \qquad ( 3 )$$

$$θ = Arctan ( \frac{{S}_{y}}{{S}_{x}} ) \qquad ( 4 )$$

In the embodiment, in the analysis of the particle of interest, of the size S and the angle θ, reference is made to the angle θ, but alternatively, reference may be made to both the size S and the angle θ.

Next, the second conversion method will be described. For example, when a segmented backscattered electron detector which is segmented into 5 or more segments is employed, the second conversion method may be employed. The second conversion method applies discrete Fourier transform with respect to the intensity distribution (a waveform formed from a plurality of signal intensities arranged in the order of angles).

With the application of the discrete Fourier transform on the intensity distribution, a complex number F(k) represented by following Equation (5) is determined for each wavenumber k (that is, for each frequency).

$$F ( k ) = {a}_{k} + {ib}_{k} \qquad ( 5 )$$

The complex number F(k) is represented as a vector Vk on a complex plane, as described below.

$${V}_{k} = ( {a}_{k} , {b}_{k} ) \qquad ( 6 )$$

More specifically, the complex number F(k) is represented by the following Equation (7).

$$F ( k ) = {\sum }_{n = 0}^{N - 1} f ( n ) {e}^{- i \frac{2 π kn}{N}} \qquad ( 7 )$$

Here, N represents the number of detection regions, and n represents an index number of the detection region. As described above, k represents the wavenumber. For the identification of the shape of the sample surface, it suffices to look into the case of k=1. The function f(n) represents a signal intensity acquired at an nth detection region.

When the wavenumber k is 1, the complex number F (1) is represented as follows.

$$F ( 1 ) = {a}_{1} + {ib}_{1} \qquad ( 8 )$$

The signal intensity observed by the backscattered electron detector as a whole is determined by substituting 0 into k. Specifically, the signal intensity is as follows.

$$F ( 0 ) = {\sum }_{n = 0}^{N - 1} f ( n ) \qquad ( 9 - 1 )$$

$$= {a}_{0} \qquad ( 9 - 2 )$$

The size S and the angle θ of the vector are determined as follows, assuming k=1.

$$S = \frac{\sqrt{{a}_{1}^{2} + {b}_{1}^{2}}}{{a}_{0}} \qquad ( 10 )$$

$$θ = arg ( {a}_{1} + {ib}_{1} ) \qquad ( 11 )$$

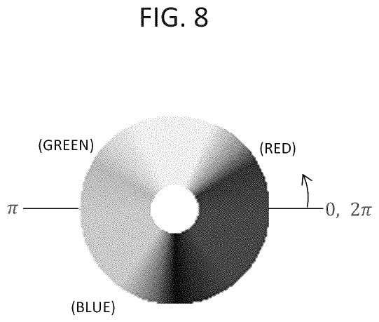

FIG. 8 shows a color space (more specifically, the HSV color space). For example, in the illustrated color space, the angle is correlated to the hue (Hue), and a position on a radial direction is correlated to brightness (Brightness). A color particle image may be produced by representing a combination of the direction and the magnitude of the vector determined in the above-described manner with a combination of the hue and the brightness.

Next, extraction of the candidate particle (convex region) will be described. Because the angle array corresponds to a vector array, the angle array can be regarded as a vector field. By applying a vector calculation for determining divergences with respect to the angle array, each individual convex region can be extracted. Conversely, each individual concave region can be excluded from the analysis target.

The process will be more specifically described. The complex number represented by above-described Equation (5) can be represented as a vector, as shown by above-described Equation (6). When the shape of the sample plane is to be considered, a case of k=1 may be examined. Here, if m and n are unit vectors, the vector field is represented as follows.

$${W}_{k} = {a}_{k} m + {b}_{k} m \qquad ( 12 )$$

The divergence of the vector field is calculated by the following Equation (13).

$$\text{?} \qquad ( 13 )$$

$$\text{?} \text{indicates text missing or illegible when filed}$$

Here, the operator (nabla) ∇ is defined as follows.

$$∇ = m \frac{\partial }{\partial x} + n \frac{\partial }{\partial y} \qquad ( 14 )$$

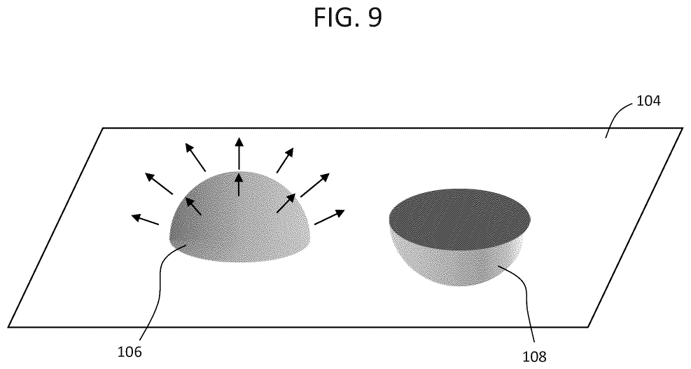

A divergence array is formed by a plurality of divergences corresponding to a plurality of coordinates. The divergence array typically includes a plurality of convex regions and a plurality of concave regions. Each convex region corresponds to a group of positive divergences. Each concave region corresponds to a group of negative divergences. In the embodiment, each of the plurality of convex regions is handled as a candidate region. Each concave region corresponds to a scar or a recess, and is excluded from the analysis target. FIG. 9 exemplifies one convex region 106 and one concave region 108 included in the beam scanning range.

For example, a binarized image is produced by applying a threshold process on the divergence array with a positive threshold. Then, through a labeling process on the binarized image, each convex region is extracted as a candidate region. Each candidate region is an independent, closed region.

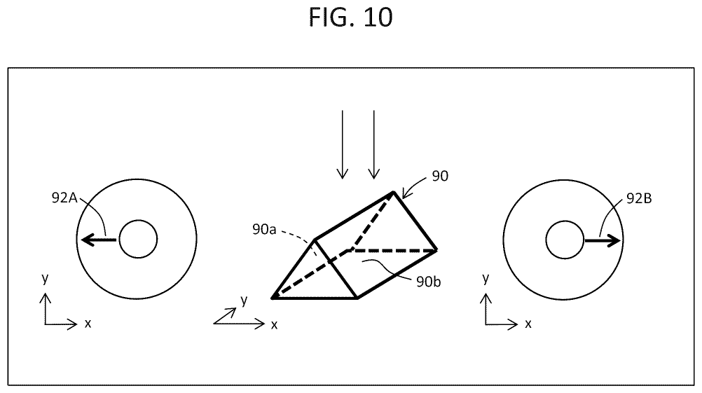

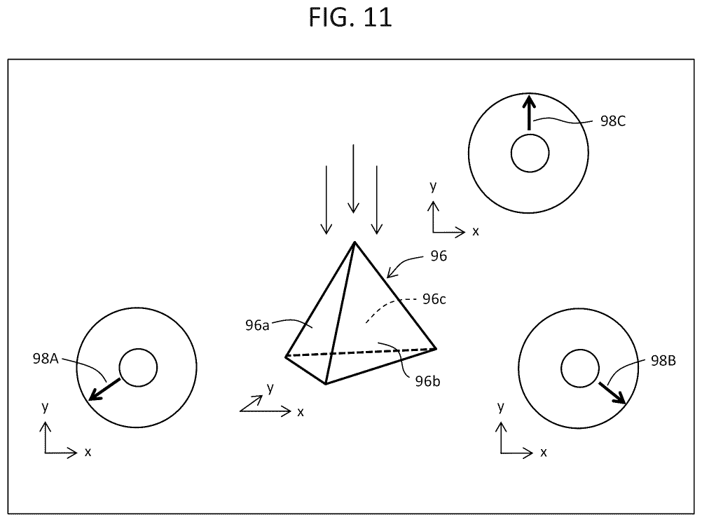

The normalization will now be described. FIG. 10 shows a first shape 90. The first shape 90 corresponds to a triangular prism having a laterally inclined orientation. The first shape 90 has two inclined surfaces 90a and 90b. When an electron beam is illuminated with respect to a measurement point on the inclined surface 90a, and a signal from the measurement point is observed, a first angle (first vector) 92A is calculated. On the other hand, when an electron beam is illuminated with respect to a measurement point on the inclined surface 90b, and a signal from the measurement point is observed, a second angle (second vector) 92B is calculated.

When viewed from an electron beam source, the first shape has a two-fold symmetry. With the scanning of the electron beam with respect to the first shape 90, a group of first angles and a group of second angles are observed. An “n-fold symmetry” refers to a property that, when a certain model is rotated by an angle of (360/n) degrees, the model after the rotation coincides with the model before the rotation.

In order to identify a shape with the two-fold symmetry, each of the first angles is multiplied by 2, and each of the second angles is multiplied by 2. With this process, all of the angles after the multiplication become equal to each other. For example, when the first angle θ1 is multiplied by 2, a value of (2×θ1) is determined. When the second angle, (θ1+180), is multiplied by 2, a value of (2×θ1+360) is determined, which is nothing other than (2×θ1). In this manner, the normalization is a process for distinguishing a shape of interest from other shapes by multiplying each angle by a coefficient corresponding to the shape of interest.

For reference, FIG. 11 shows a second shape 96. The second shape 96 is a triangular pyramid. The second shape 96 has 3 inclined surfaces 96a, 96b, and 96c. When an electron beam is illuminated with respect to a measurement point on the inclined surface 96a, and a signal from the measurement point is observed, a first angle (first vector) 98A is calculated. When an electron beam is illuminated with respect to a measurement point on the inclined surface 96b, and a signal from the measurement point is observed, a second angle (second vector) 98B is calculated. When an electron beam is illuminated with respect to an observation point on the inclined surface 96c and a signal from the measurement point is observed, a third angle (third vector) 98C is calculated. When viewed from the electron beam source, the second shape 96 has a three-fold symmetry. With the scanning of the electron beam with respect to the second shape 96, a group of first angles, a group of second angles, and a group of third angles are observed.

When the three-fold symmetry is recognized, if each of the first angles is multiplied by 3, each of the second angles is multiplied by 3, and each of the third angles is multiplied by 3, all of the angles after the multiplication become equal to each other. For example, when the first angle θ1 is multiplied by 3, a value of (3×θ1) is determined. When the second angle (θ1+120) is multiplied by 3, a value of (3×θ1+360) is determined, which is nothing other than (3×θ1). When the third angle (θ1+240) is multiplied by 3, a value of (3×θ1+720) is determined, which is nothing other than (3×θ1).

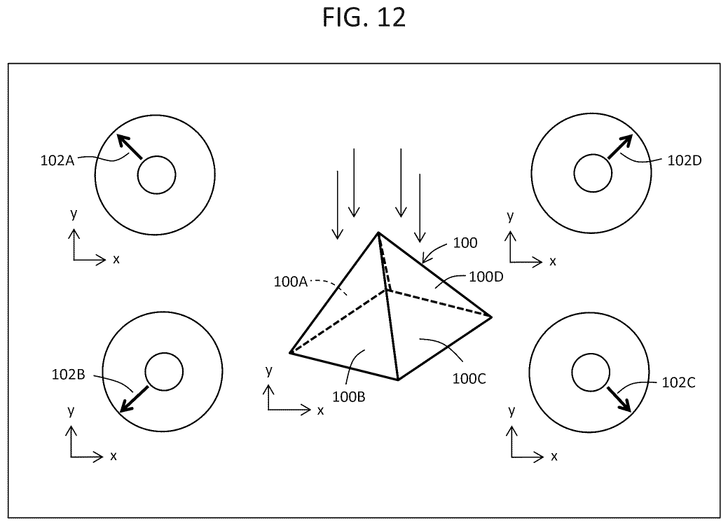

For reference, FIG. 12 shows a third shape 100. The third shape 100 is a quadrangular pyramid. The third shape 100 has four inclined surfaces 100a, 100b, 100c, and 100d. When an electron beam is illuminated with respect to a measurement point on the inclined surface 100a, and a signal from the measurement point is observed, a first angle (first vector) 102A is calculated. When an electron beam is illuminated with respect to a measurement point on the inclined surface 100b, and a signal from the measurement point is observed, a second angle (second vector) 102B is calculated. When an electron beam is illuminated with respect to a measurement point on the inclined surface 100c and a signal from the measurement point is observed, a third angle (third vector) 102C is calculated. When an electron beam is illuminated with respect to a measurement point on the inclined surface 100d and a signal from the measurement point is observed, a fourth angle (fourth vector) 102D is calculated. When viewed from the electron beam source, the third shape 100 has a four-fold symmetry. With the scanning of the electron beam with respect to the third shape 100, a group of first angles, a group of second angles, a group of third angles, and a group of fourth angles are observed.

When the four-fold symmetry is recognized, if each of the first angles is multiplied by 4, each of the second angles is multiplied by 4, each of the third angles is multiplied by 4, and each of the fourth angles is multiplied by 4, all of the angles after the multiplication become equal to each other. Detailed description of this process will be omitted.

As described, by applying normalization corresponding to the shape of interest with respect to the angle array, it becomes easy to identify a particular particle. In identifying the asbestos particle, a coefficient of 2 is employed. Alternatively, a particle having an arbitrary shape may be identified. In this process, the coefficient for the normalization may be designated by the user.

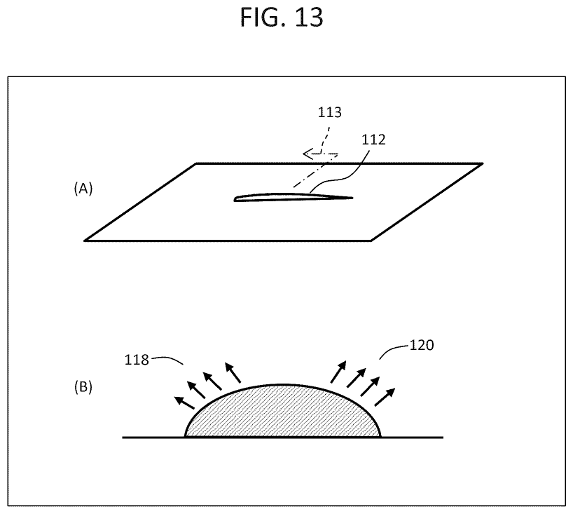

FIG. 13 schematically shows the asbestos particle. In FIG. 13, part (A) shows a background surface (base material surface), and an asbestos particle 112 exists on the background surface. Part (B) shows a lateral cross section of the asbestos particle (with reference numeral 113 indicating a position of the lateral cross section). The asbestos particle has a shape close to the above-described first shape. Therefore, a group of first angles 118 acquired from one-side surface of the asbestos particle and a group of second angles 120 acquired from the other-side surface of the asbestos particle are in a two-fold symmetrical relationship.

Next, a method of analyzing the particle of interest, more specifically, a method of identifying the asbestos particle, will be described. First, a first analysis method will be described, and later, a second analysis method will be described.

In the first analysis method, for each candidate particle, dispersion information is calculated based on a group of normalized angles acquired from the candidate particle, and based on the dispersion information, a determination is made as to whether or not the candidate particle is the particle of interest. More specifically, the method proceeds as follows.

A group of normalized angles acquired from the candidate particle is represented as follows.

$${θ}_{j} ( j = 1 , 2 , 3 , … N ) \qquad ( 15 )$$

When each of the normalized angles is regarded to be a unit vector, the following composite vector is defined through synthesis of a group of unit vectors corresponding to the group of normalized angles.

$$( {\sum }_{j = 1}^{N} cos {ϑ}_{j} , {\sum }_{j = 1}^{N} sin {ϑ}_{j} ) = {\sum }_{j = 1}^{N} {e}^{i {ϑ}_{j}} \qquad ( 16 )$$

An average value θ_{AVE} of angles θ₁ to θ_{N} is defined as follows.

$${θ}_{ave} = arg ( {\sum }_{j} {e}^{i {θ}_{j}} ) \qquad ( 17 )$$

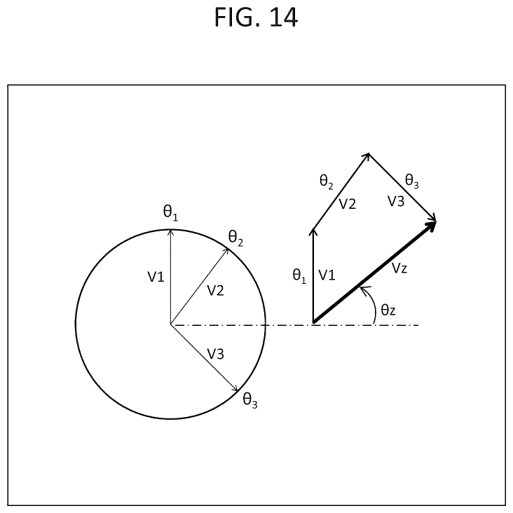

FIG. 14 shows three unit vectors V₁, V₂, and V₃ corresponding to three angles θ₁, θ₂, and θ₃. In addition, FIG. 14 shows a composite vector V_{z} defined through synthesis of the three unit vectors V₁, V₂, and V₃. The argument Oz of the composite vector V_{z} corresponds to an average value of the angles.

Based on the composite vector V_{z}, a length r of an average composite vector is determined as follows.

$$r = abs ( \frac{1}{N} {\sum }_{j = 1}^{N} {e}^{i {ϑ}_{j}} ) \qquad ( 18 )$$

An absolute value of each complex number is 1. Further, in Equation (18) described above, as a total sum of the complex number is divided by the number of angles, N, 0≤r≤1. In the embodiment, the dispersion information d is defined by following Equation (19).

$$d = 1 - r \qquad ( 19 )$$

Here, 0≤d≤1. When the group of normalized angles exhibit uniformity, the dispersion information d becomes smaller. More specifically, when the candidate particle is the asbestos particle, the dispersion information d becomes small. When the group of normalized angles exhibit diversity, the dispersion information d becomes greater. Alternatively, as information in place of the dispersion information, the above-described parameter r may be employed, or another index may be employed.

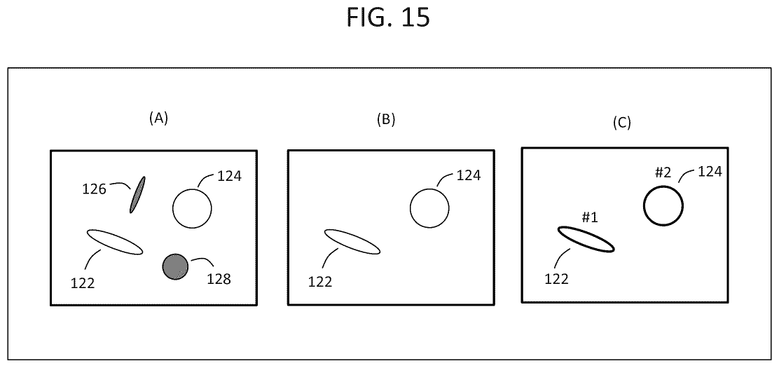

In FIG. 15, part (A) shows a divergence array determined through vector calculation. The divergence array includes convex regions 122 and 124, and concave regions 126 and 128. Part (B) shows a result of the binarization process (result of extraction of the candidate particles). As illustrated, the convex regions 122 and 124 remain, and the concave regions 126 and 128 are discarded. Part (C) shows a result of labeling. A label of #1 is assigned to the convex region 122, and a label of #2 is assigned to the convex region 124.

After the processes as described above, a group of normalized angles corresponding to the convex region 122 are extracted, and are evaluated. More specifically, based on dispersion information determined from the group of normalized angles, a determination is made as to whether or not the convex region 122 is the particle of interest (more specifically, the asbestos particle). Similarly, a group of normalized angles corresponding to the convex region 124 are extracted, and based on the group of normalized angles, a determination is made as to whether or not the convex region 124 is the particle of interest.

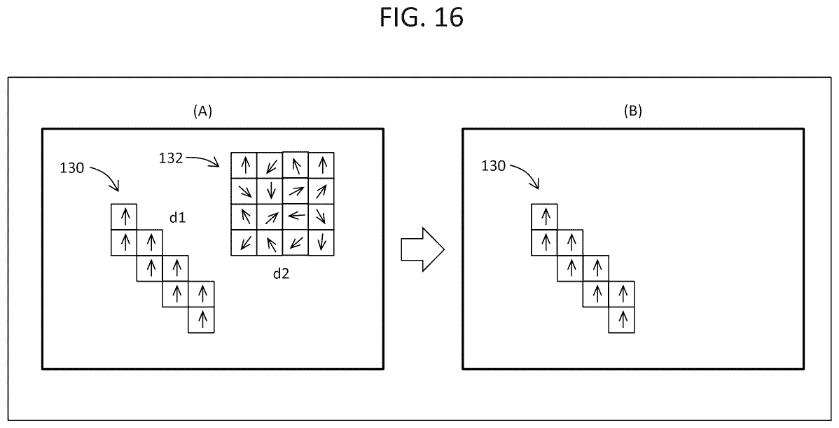

FIG. 16 shows an example of evaluation of the group of normalized angles. Part (A) shows a state before the evaluation, and part (B) shows a state after the evaluation. A group of normalized angles corresponding to a candidate particle 130 exhibits uniformity, and the dispersion information d1 is calculated based on the group of normalized angles. On the other hand, a group of normalized angles belonging to a candidate particle 132 exhibit diversity, and dispersion information d2 is calculated based on the group of normalized angles.

For example, each of the dispersion information d1 and d2 is compared with a threshold dx. In the illustrated example, the dispersion information d1 is smaller than the threshold dx, and the dispersion information d2 is greater than the threshold dx. Accordingly, the candidate particle 130 is determined to be the particle of interest. The candidate particle 132 is excluded.

Next, the second analysis method will be described. In the second analysis method, a histogram (normalized angle histogram) is created for each candidate region, and the candidate particle is analyzed based on the histogram.

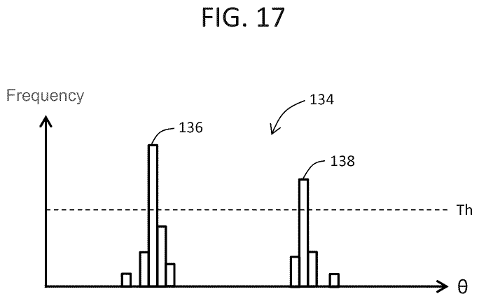

For example, when the candidate particle has the needle shape, a histogram having one peak is caused. When the candidate particle corresponds to an intersection (combination) of two needle shapes, as illustrated in FIG. 17, a histogram 134 having two peaks 136 and 138 is caused. When the candidate region is a circular region, a histogram having a large number of low peaks is caused, or a histogram having no clear peak is caused.

By evaluating the histogram in the manner described above, the shape of the candidate particle can be analyzed.

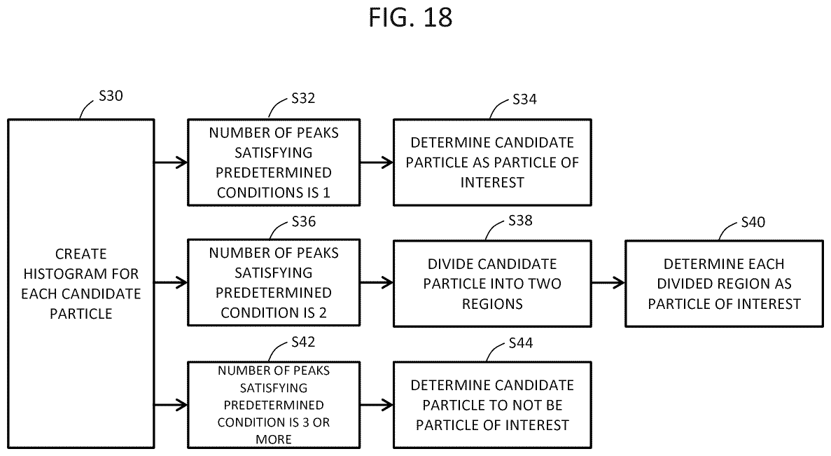

FIG. 18 shows a specific example of the second analysis method. In S30, a histogram is created based on the group of normalized angles corresponding to the candidate particle. In S32, it is determined that the number of peaks satisfying a predetermined condition in the histogram is 1. In S34, the candidate particle is determined to be the particle of interest. For example, the predetermined condition is satisfied when a level of the peak is greater than or equal to a certain value. In addition, a width of the peak may be further evaluated.

In S36, it is determined that the number of peaks satisfying a predetermined condition in the histogram is 2. In S38, the candidate particle is divided into two regions (divided regions) corresponding to the two peaks. In S40, each of the divided regions is determined as the particle of interest. In S42, it is determined that the number of peaks satisfying a predetermined condition in the histogram is greater than or equal to 3. In S44, the candidate particle is determined to not be the particle of interest.

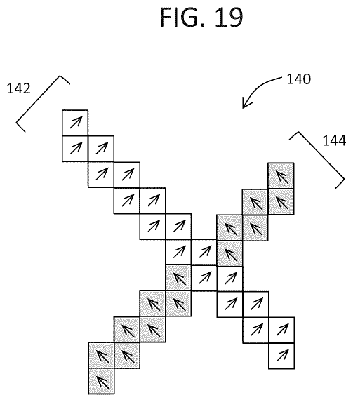

FIG. 19 shows specifics of the processing of S38 described above. A candidate particle 140 is divided into two regions 142 and 144. In this case, the regions 142 and 144 respectively corresponding to the peaks may be identified based on the histogram. Alternatively, the candidate particle may be divided into three or more regions. Alternatively, from among the normalized angle array, a normalized angle or a normalized angle range which results in the highest frequency may be identified, and a normalized angle or a normalized angle range which results in the second highest frequency may then be identified. Such a process can also be considered as a process based on the histogram.

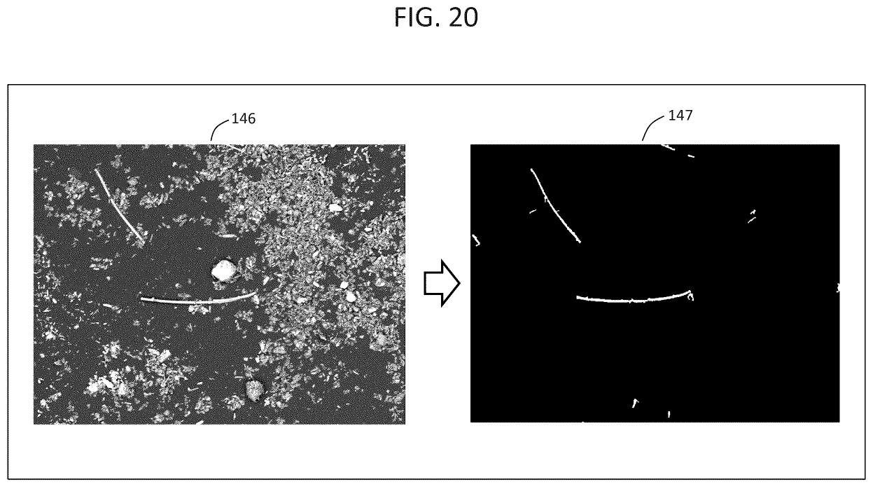

FIG. 20 shows a backscattered electron image 146 and a particle-of-interest image 147. The backscattered electron image 146 is a backscattered electron composition image. In the particle-of-interest image 147, each asbestos particle is represented as a large, white streak.

According to the particle analysis method of the embodiment of the present disclosure, a particle having a needle shape or a string shape can be precisely identified without being affected by scars and recesses. In the particle analysis method according to the embodiment of the present disclosure, in order to further improve the precision of identification, an aspect ratio may be calculated for each particle, and the aspect ratio may be taken into consideration during the particle analysis.

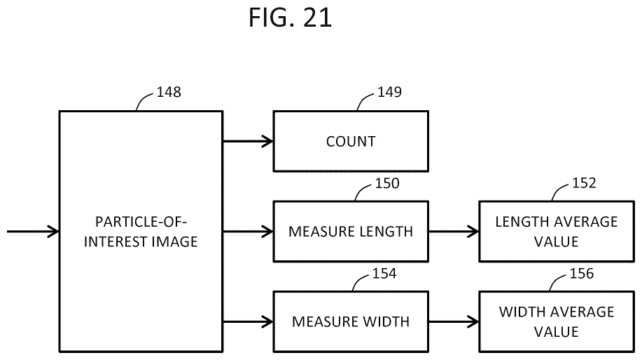

FIG. 21 shows content of a calculation executed by the calculator illustrated in FIG. 1. Based on a particle-of-interest image 148, particles of interest included therein are counted (refer to reference numeral 149). For example, the number of particles of interest per unit area may be calculated. In addition, based on the particle-of-interest image 148, a length may be measured for each particle of interest (refer to reference numeral 150), and an average length may be calculated based on a plurality of lengths determined from a plurality of particles of interest (refer to reference numeral 152). Further, based on the particle-of-interest image 148, a width may be measured for each particle of interest (refer to reference numeral 154), and an average width may be calculated based on a plurality of widths determined from a plurality of particles of interest (refer to reference numeral 156). Alternatively, whether or not each particle of interest is the asbestos particle may be determined based on the length, the width, the area, or the like of each particle of interest.

For example, the above-described sequence of processes may be executed in a particle measurement system having a laser microscope. In this case, a segmented detector which detects a laser beam from a sample may be employed. In the above-described embodiment of the present disclosure, an elongated crystal may be analyzed in place of the asbestos particle. Alternatively, particles having a shape other than an elongated shape may be analyzed.

1. A particle analysis apparatus comprising:
a processor configured to process, for each coordinate in a beam scanning range on a sample, an intensity distribution acquired by detecting a signal emitted from the coordinate with a detection region array, wherein
the processor is configured to:
calculate an angle representing an orientation of a plane at the coordinate based on the intensity distribution;
apply normalization corresponding to a shape of interest with respect to a plurality of angles corresponding to a plurality of coordinates in the beam scanning range, to thereby calculate a plurality of normalized angles; and
analyze, for each candidate particle in the beam scanning range, whether the candidate particle is a particle of interest, based on a group of normalized angles corresponding to the candidate particle.

2. The particle analysis apparatus according to claim 1, wherein
the processor is configured to calculate the plurality of normalized angles by multiplying each of the plurality of angles by a coefficient corresponding to the shape of interest.

3. The particle analysis apparatus according to claim 2, wherein
the shape of interest is a needles shape or a string shape, and
the coefficient is 2.

4. The particle analysis apparatus according to claim 1, wherein
the processor is configured to determine a convex region in the beam scanning range as the candidate particle based on the plurality of angles corresponding to the plurality of coordinates.

5. The particle analysis apparatus according to claim 4, wherein
the processor is configured to determine the convex region by applying calculation for determining divergences with respect to the plurality of angles corresponding to the plurality of coordinates.

6. The particle analysis apparatus according to claim 1, wherein
the processor is configured to:
calculate dispersion information based on the group of normalized angles corresponding to the candidate particle; and
analyze whether the candidate particle is the particle of interest, based on the dispersion information.

7. The particle analysis apparatus according to claim 1, wherein
the processor is configured to:
create a histogram based on the group of normalized angles corresponding to the candidate particle; and
analyze whether the candidate particle is the particle of interest, based on the histogram.

8. The particle analysis apparatus according to claim 7, wherein
the processor is configured to:
determine that a shape of the candidate particle is a combination of a plurality of shapes of interest, based on the histogram; and
divide the candidate particle into a plurality of particles of interest when the shape of the candidate particle is a combination of the plurality of shapes of interest.

9. A method of analyzing a particle executed by an information processing apparatus, the method comprising:
calculating, for each coordinate in a beam scanning range on a sample, an angle representing an orientation of a plane at the coordinate based on an intensity distribution acquired by detecting a signal emitted from the coordinate with a detection region array;
applying normalization corresponding to a shape of interest with respect to a plurality of angles corresponding to a plurality of coordinates in the beam scanning range, to thereby calculate a plurality of normalized angles; and
analyzing, for each candidate particle in the beam scanning range, whether the candidate particle is a particle of interest, based on a group of normalized angles corresponding to the candidate particle.

10. A non-transitory recording medium storing a program for executing a particle analysis method on an information processing apparatus, the program, when executed, causing the information processing apparatus to execute a process comprising:
calculating, for each coordinate in a beam scanning range on a sample, an angle representing an orientation of a plane at the coordinate based on an intensity distribution acquired by detecting a signal emitted from the coordinate with a detection region array;
applying normalization corresponding to a shape of interest with respect to a plurality of angles corresponding to a plurality of coordinates in the beam scanning range, to thereby calculate a plurality of normalized angles; and
analyzing, for each candidate particle in the beam scanning range, whether the candidate particle is a particle of interest, based on a group of normalized angles corresponding to the candidate particle.
